(19) United States
(12) Patent Application Publication
(10) Pub. No.: US 2008/0283971 A1
(43) Pub. Date: Nov. 20, 2008

(54) Semiconductor Device and Its Fabrication Method

(75) Inventors: Chien-Ping Huang, Taichung (TW); Chin-Huang Chang, Taichung (TW); Chih-Ming Huang, Taichung (TW)

Correspondence Address: WPAT, PC;INTELLECTUAL PROPERTY ATTORNEYS, 2030 MAIN STREET, SUITE 1300, IRVINE, CA, 92614, US

(73) Assignee: SILICONWARE PRECISION INDUSTRIES CO., LTD., Taichung (TW)

(21) Appl. No.: 12/102,213

(22) Filed: Apr. 14, 2008

(30) Foreign Application Priority Data
Apr. 13, 2007 (TW) 096112971

(51) Int. Cl. H01L 23/488; H01L 21/304

(52) U.S. Cl. 257/620; 438/462; 257/E23.023; 257/E21.238

(57) ABSTRACT

A semiconductor device and a fabrication method thereof are disclosed. The method includes attaching a wafer with a plurality of chips on a carrier board having an insulating layer, a plurality of conductive circuits and a bottom board; forming a plurality of first grooves between solder pads of adjacent chips to expose the conductive circuits, and filling the first grooves with an insulating adhesive layer; forming second grooves in the insulating adhesive layer; and cutting among the chips to separate the chips from one another.

### BACKGROUND OF THE INVENTION

1. Field of the Invention

This invention generally relates to semiconductor devices and fabrication method thereof, and more specifically, to semiconductor devices capable of being vertically stacked and fabrication method thereof.

2. Description of Related Art

Conventional semiconductor packages are generally presented as a form of multi-chip module (MCM), wherein at least two chips are mounted on a substrate or a lead frame of a single semiconductor package.

Please refer to FIG. 1, which illustrates a conventional multi-chip semiconductor package with horizontally spaced chips. As shown in FIG. 1, the semiconductor package includes a substrate 100, a first chip 110 having an active surface 110a and an opposite non-active surface 110b, wherein the non-active surface 110b of the first chip 110 is adhered to the substrate 100 and the active surface 110a of the first chip 110 is electrically connected to the substrate 100 via first conductive wires 120, and a second chip 140 having an active surface 140a and an opposite non-active surface 140b, wherein the non-active surface 140b of the second chip 140 is adhered to the substrate 100 and spaced apart from the first chip 110 at a certain distance, and the active surface 140a of the second chip 140 is electrically connected to the substrate 100 via second conductive wires 150.

A major disadvantage of the aforementioned multi-chip semiconductor package is that the chips must be spaced apart from each other at a certain distance so as to prevent miscontact between the conductive wires of the adjacent chips. Thus, when a plurality of chips are mounted to a substrate, a large die attachment area is required on the substrate to accommodate the chips, thereby increasing the fabrication cost and making it difficult to obtain thinner, lighter and smaller packages.

Please further refer to FIG. 2, which illustrates a multi-chip stack structure disclosed by U.S. Pat. No. 6,538,331. A first chip 110′ and a second chip 140′ are stack mounted on a substrate 100′, and the second chip 140′ is offset a certain distance from the first chip 110′ so as to facilitate bonding of wires from the first chip 110′ and the second chip 140′ to the substrate 100′ respectively.

Although such a stack structure can save more substrate space than the abovementioned semiconductor package with horizontally spaced chips, it still requires a wire bonding technique to electrically connect the chips to the substrate. As a result, quality of electrical connection between the chips and the substrate would be adversely affected by length of bonding wires. Further, the number of chips that can be accommodated by the stack structure is constrained by spaces required by chip offset and bonding wire layout.

According to the abovementioned drawbacks, a TSV (Through Silicon Via) technique is disclosed by U.S. Pat. Nos. 6,642,081, 5,270,261, and 6,809,421. Through the TSV technique, a plurality of semiconductor chips can be vertically stacked and electrically connected to one another. However, as the TSV technique has a complicated fabrication process and high fabrication cost, its application value in the industry is quite limited.

Hence, it is a highly urgent issue in the industry to provide a technique of multi-chip stack structure and a fabrication method thereof which can effectively integrate more chips in a package without increasing die attachment area of substrate, avoid poor electrical performance caused by using the wire bonding technique, and also avoid complicated fabrication process and high fabrication cost caused by using the TSV technique, thereby solving the drawbacks of the prior arts.

### SUMMARY OF THE INVENTION

In view of the disadvantages of the prior art mentioned above, it is an objective of the present invention to provide a semiconductor device and a fabrication method thereof, through which more chips can be integrated in a semiconductor package without increasing die attachment area.

It is another objective of the present invention to provide a semiconductor device and a fabrication method thereof that provide a simple fabrication process, thereby avoiding complicated fabrication process and high production cost caused by using the TSV technique.

It is a further objective of the present invention to provide a semiconductor device and a fabrication method thereof through which a plurality of chips can be directly electrically connected to one another, thereby avoiding poor electrical performance caused by using the wire bonding technique.

To achieve the aforementioned and other objectives, a fabrication method of a semiconductor device is provided according to the present invention, which comprises: providing a carrier board and a wafer having a plurality of chips, wherein the wafer and the chips each has an active surface and an opposite non-active surface, a plurality of solder pads are formed on the active surfaces of the chips, and the carrier board includes a bottom board and a plurality of conductive circuits disposed on the bottom board, the non-active surface of the wafer is mounted to the bottom board and the conductive circuits through an insulating layer; forming a plurality of first grooves between solder pads of adjacent chips; filling up the first grooves with an insulating adhesive layer, and forming second grooves in the insulating adhesive layer, wherein the second grooves have a depth sufficient to at least reach locations of the conductive circuits of the carrier board; forming a metal layer in the second grooves for electrically connecting the solder pads of adjacent chips and the conductive circuits of the carrier board; cutting among the chips to separate the chips on the carrier board from one another, and adhering a first tape on the chips; removing the bottom board of the carrier board to expose the conductive circuits and the insulating layer, and adhering a second tape on the conductive circuits and the insulating layer; and removing the first tape so as to pick up the chips from the second tape, thereby forming a plurality of semiconductor devices.

In the present invention, the carrier board is formed by the steps of providing a bottom board made of a metal material; forming a first resist layer on the bottom board, and forming a plurality of apertures in the first resist layer to expose the bottom board; forming conductive circuits in the apertures by electroplating; and removing the first resist layer. The insulating layer can be pre-disposed on the bottom board and the conductive circuits so as to become a part of the carrier board and thereafter the wafer can be mounted on the insulating layer. Alternatively, the insulating layer can be pre-disposed on the non-active surface of the wafer before the wafer is mounted to the conductive circuits and the bottom board of the carrier board.

The present invention further discloses a semiconductor device, which includes an insulating layer having a top surface and an opposite bottom surface; conductive circuits disposed on periphery of the bottom surface of the insulating layer; a chip having an active surface and an opposite non-active surface, wherein the non-active surface of the chip is mounted on the top surface of the insulating layer, and a plurality of solder pads are formed on the active surface of the chip; an insulating adhesive layer formed on sides of the chip and the insulating layer; and a metal layer formed on edges of the active surface of the chip and sides of the insulating adhesive layer for electrically connecting the solder pads of the chip to the conductive circuits on the bottom surface of the insulating layer.

In addition, according to the present invention, after the metal layer is formed, a dielectric layer can further be formed on the active surfaces of the chips and the metal layer. The bottom board is removed, and a solder mask layer is formed on the insulating layer. The solder mask layer has a plurality of apertures to expose the conductive circuits such that conductive elements such as solder balls can be mounted thereon, and then the whole structure is cut between the chips to separate the chips from one another, thereby forming a plurality of wafer-level chip scale semiconductor devices.

In view of the above, the present invention mainly includes providing a wafer having a plurality of chips, and mounting the wafer on a carrier board that has an insulating layer, a plurality of conductive circuits, and a bottom board, and forming a plurality of first grooves between solder pads of adjacent chips to expose the conductive circuits; then filling the first grooves with an insulating adhesive layer; forming second grooves in the insulating adhesive layer, wherein the second grooves should be deep sufficient to reach the conductive circuits on the carrier board, so as to form a metal layer for electrically connecting the conductive circuits and the solder pads on the active surfaces of adjacent chips; cutting among the chips to separate the chips on the carrier board from one another; adhering a first tape on the plurality of chips, removing the bottom board of the carrier board to expose the conductive circuits and the insulating layer; adhering a second tape on the conductive circuits and the insulating layer; and removing the first tape such that the chips can be easily picked up from the second tape, thereby forming a plurality of semiconductor devices.

In the subsequent fabrication process, the conductive circuits of a semiconductor device can be thermally compressed and electrically connected to a substrate or the metal layer of another semiconductor device so as to form a 3-D multi-chip stack structure. Thus, the present invention is capable of efficiently integrating more chips to enhance electrical function without increasing die attachment area. Moreover, the present invention not only avoids poor electrical performance caused by using the wire bonding technique but also avoids complicated fabrication process and high fabrication cost caused by using the TSV technique.

### BRIEF DESCRIPTION OF DRAWINGS

The present invention can be more fully understood by reading the following detailed description of the preferred embodiments, with reference made to the accompanying drawings, wherein:

FIG. 1 is a sectional view diagram illustrating a conventional multi-chip semiconductor package with multiple chips horizontally spaced from each other;

FIG. 2 is a sectional view diagram illustrating a semiconductor package of multi-chip stack structure according to U.S. Pat. No. 6,538,331;

FIGS. 3A through 3L are diagrams of a semiconductor device and a fabrication method thereof according to the first embodiment of the present invention;

FIG. 3D′ is a diagram illustrating another embodiment of connecting a wafer to a carrier board according to the present invention;

FIG. 4 is a sectional view diagram illustrating a stack structure of semiconductor devices according to the first embodiment of the present invention;

FIGS. 5A through 5D are diagrams illustrating a semiconductor device and a fabrication method thereof according to the second embodiment of the present invention; and

FIG. 6 is a sectional view diagram illustrating a stack structure of semiconductor devices according to the second embodiment of the present invention.

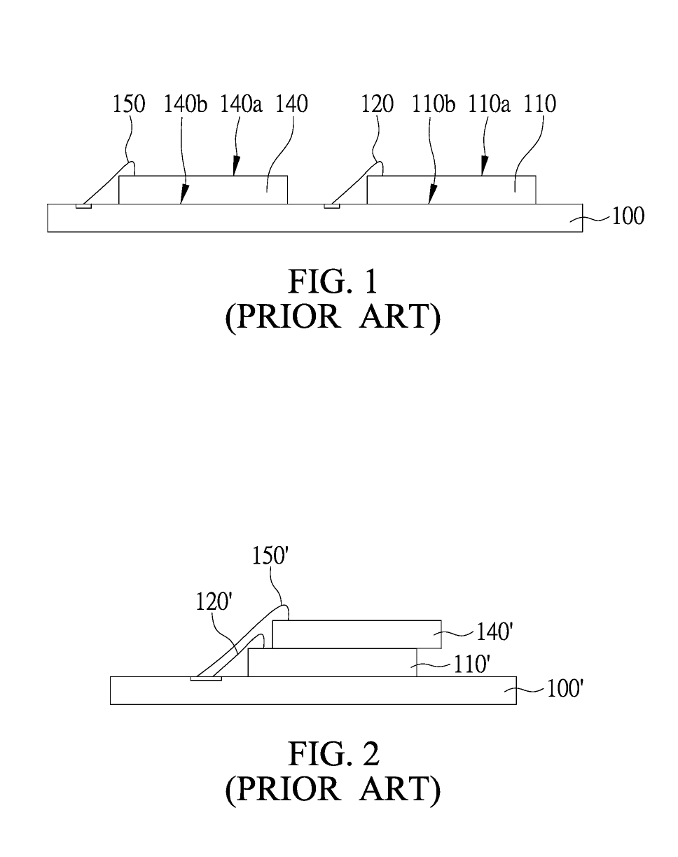

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

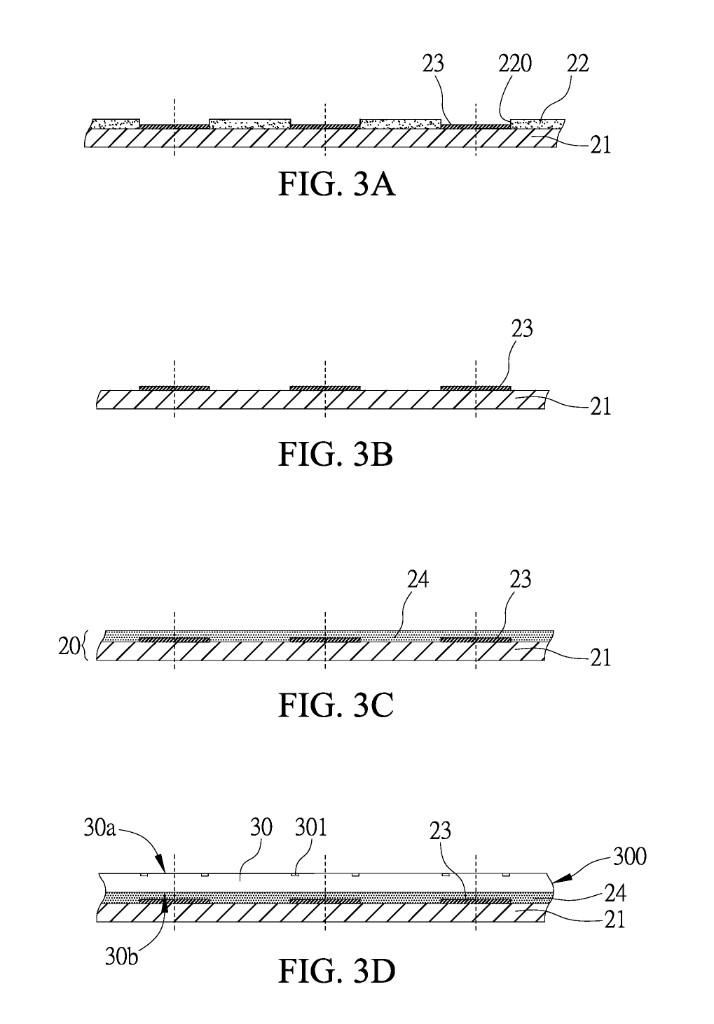

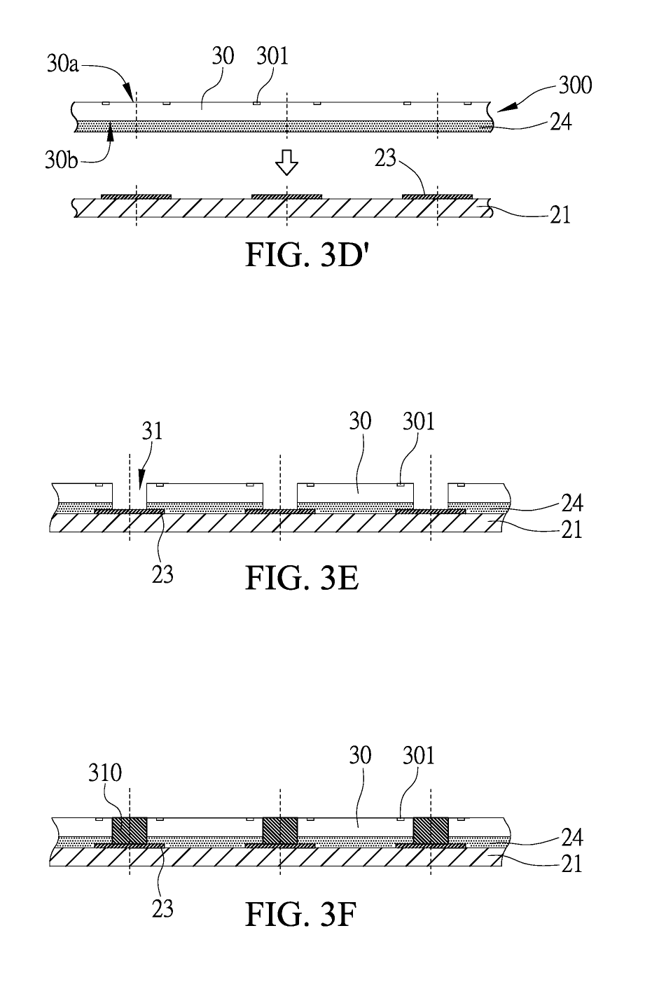

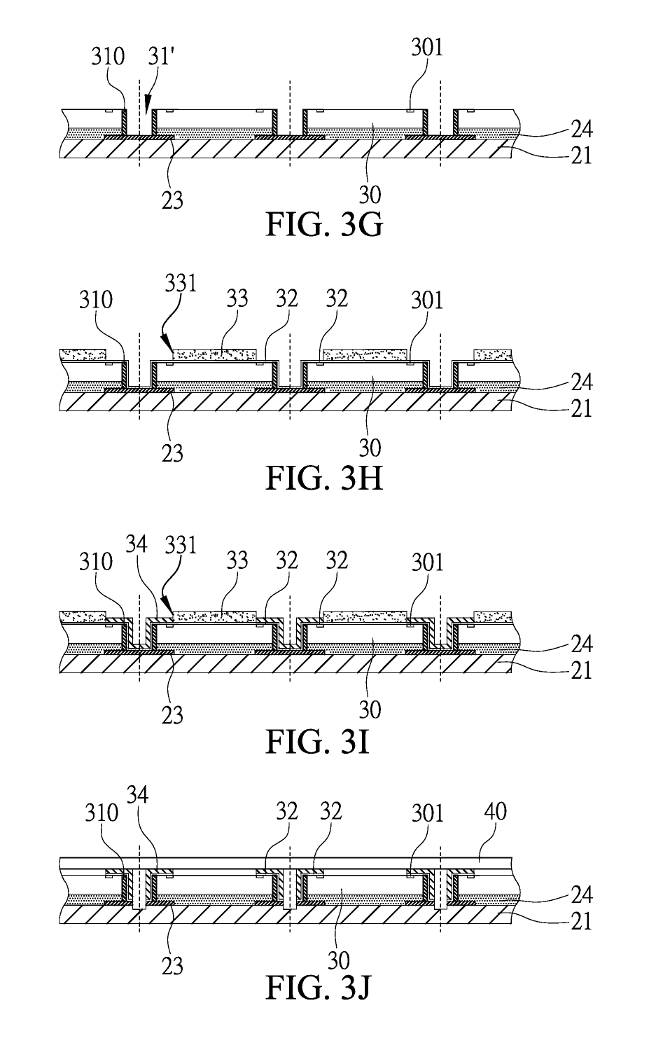

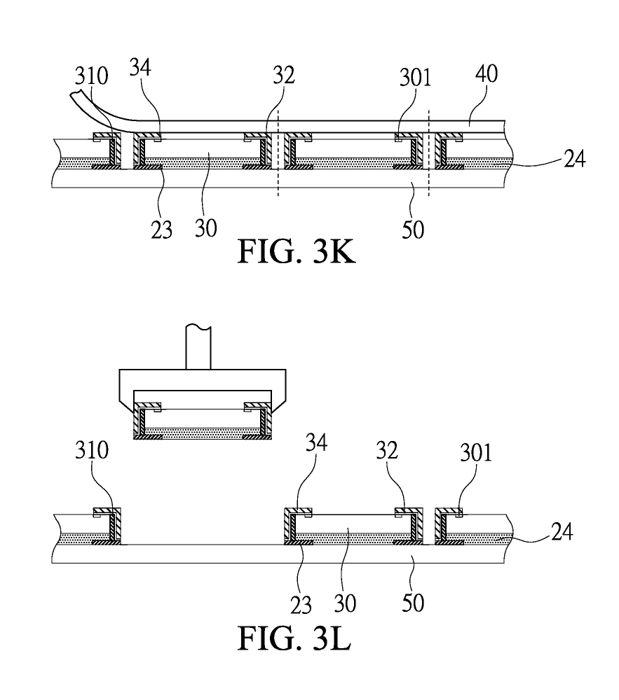

Please refer to FIGS. 3A through 3L, which are diagrams of a semiconductor device and a fabrication method thereof according to the first embodiment of the present invention.

As shown in FIGS. 3A through 3C, a bottom board 21 made of such as copper (Cu) is provided. A first resist layer 22 is formed on the bottom board 21, a plurality of apertures 220 are formed in the first resist layer 22 to expose part of the bottom board 21, and a plurality of conductive circuits 23 made of such as gold/palladium/nickel (Au/Pd/Ni) are formed in the apertures 220 by electroplating. The first resist layer 22 is removed, and an insulating layer 24 is formed on the bottom board 21 to cover the conductive circuits 23 and the bottom board 21. The insulating layer 24 is made of such as B-stage epoxy resin or polyimide. Thus, a carrier board 20 that includes the bottom board 21, the plurality of conductive circuits 23 on the bottom board 21, and the insulating layer 24 that covers the bottom board 21 and the conductive circuits 23 is formed.

As shown in FIG. 3D, a wafer 300 including a plurality of chips 30 are provided and mounted on the insulating layer 24 of the carrier board 20. The wafer 300 and the chips 30 each has an active surface 30a and an opposite non-active surface 30b, and a plurality of solder pads 301 are formed on the active surface 30a of each chip 30. In addition, a thinning process such as grinding can be pre-performed on the wafer 300 so as to make the wafer have a thickness of about 50˜150 μm.

As shown in FIG. 3D′, the insulating layer 24 can alternatively be pre-formed on the non-active surfaces 30b of the wafer 300 and the chips 30, and further adhered to the conductive circuits 23 of the bottom board 21.

As shown in FIG. 3E, a plurality of first grooves 31 are formed between solder pads 301 of adjacent chips 30 by means of etching or cutting. The first grooves 31 have a depth sufficient to at least reach locations of the conductive circuit 23 of the carrier board 20.

As shown in FIGS. 3F and 3G, an insulating adhesive layer 310 is formed in the first grooves 31, and second grooves 31′ are formed respectively in the insulating adhesive layer 310 by means of etching or cutting, wherein width of the second groove 31′ is smaller than that of the first groove 31 such that part of the insulating adhesive layer 310 can be remained to cover sides of the chips 30, and the second grooves 31′ have a depth sufficient to at least reach the locations of the conductive circuits 23 of the carrier board 20. The insulating adhesive layer can be made of such as polyimide.

As shown in FIG. 3H, a conductive layer 32 is formed on the active surface of the wafer 300 and inner surfaces of the second grooves by means of sputtering or vaporizing. The conductive layer 32 is formed on the active surface of the wafer 300 and the insulating adhesive layer 310. The insulating adhesive layer 310 located between the chips 30 and the conductive layer 32 enhances the insulating property and adhesive property of the chips 30 and the conductive layers 32. The conductive layer 32 is such as an UBM (Under Bump Metallurgy) layer, which is made of such as titanium/copper/nickel (Ti/Cu/Ni), titanium wolfram/gold (TiW/Au), aluminum/nickel vanadium/copper (Al/NiV/Cu), titanium/nickel vanadium/copper (Ti/NiV/Cu), titanium wolfram/nickel (TiW/Ni), titanium/copper/copper (Ti/Cu/Cu), titanium/copper/copper/nickel (Ti/Cu/Cu/Ni), and etc.

Next, a second resist layer 33 is formed on the conductive layer 32, and a plurality of apertures 331 are formed in the second resist layer 33 corresponding in position to the second grooves 31′.

As shown in FIG. 3I, a metal layer 34 is formed in the apertures 331 of the second resist layer 33 by means of electroplating. The metal layer includes such as a copper layer and a solder layer (Cu/Solder) or a nickel layer and a solder layer (Ni/Solder), and the metal layer 34 is electrically connected to the solder pads 301 of adjacent chips 30 as well as the conductive circuits 23 of the carrier board 20.

As shown in FIG. 3J, the second resist layer 33 and the conductive layer 32 covered by the second resist layer 33 are removed by means of etching, and the whole structure is cut between the chips to separate the chips 30 on the carrier board 20 from one another. The cutting positions correspond to positions of the second grooves 31′, and the cutting width is smaller than the width of the second grooves 31′ such that part of the metal layer can be remained on edges of the active surfaces of the chips and the insulating adhesive layer beside the chips, through which the solder pads 301 of the chips 30 can still be electrically connected to the conductive circuits 23. Further, the cutting depth is deeper than the depth of the second grooves 31′ such that adjacent chips can be electrically separated from one another.

Next, a first tape 40 is adhered on the chips 30. The first tape 40 is an ultraviolet tape (U.V. tape) or a blue tape.

As shown in FIGS. 3K and 3L, the bottom board 21 of the carrier board 20 is removed, so as to expose the conductive circuits 23 and the insulating layer 24. Then, a second tape 50 is adhered on the conductive circuits 23 and the insulating layer 24. The bottom board 21 can be removed by means of etching, and the second tape 50 can be an ultraviolet tape or a blue tape.

Next, the first tape 40 is removed such that each chip 30 can be picked up from the second tape 50 for subsequent die attachment process or stack process.

In accordance with the foregoing fabrication method, the present invention further discloses a semiconductor device. The semiconductor device includes an insulating layer 24 having a top surface and an opposite bottom surface; conductive circuits 23 disposed on periphery of the bottom surface of the insulating layer 24; a chip 30 having an active surface 30a and an opposite non-active surface 30b, wherein the chip 30 is mounted on the top surface of the insulating layer 24 through its non-active surface 30b, and there are a plurality of solder pads 301 formed on the active surface 30a of the chip 30; an insulating adhesive layer 310 formed on sides of the chip 30 and the insulating layer 24; and a metal layer 34 formed on edges of the active surface 30a of the chip 30 and sides of insulating adhesive layer 310 for electrically connecting the solder pads 301 of the chip 30 to the conductive circuits 23 on the bottom surface of the insulating layer 24. In addition, a conductive layer 32 is formed between the metal layer 34 and the insulating adhesive layer 310 and also between the metal layer 34 and the chip 30. The conductive layer 32 is an UBM layer.

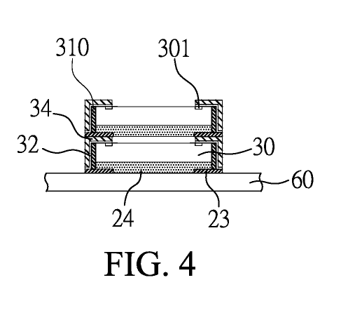

Referring to FIG. 4, in the subsequent fabrication process, a foregoing fabricated semiconductor device is picked up from the second tape, and the conductive circuits 23 of the semiconductor device is thermally compressed and electrically connected to a substrate 60 or the metal layer 34 of another semiconductor device, thereby forming a 3-D multi-chip stack structure.

In view of the above, the present invention mainly includes providing a wafer having a plurality of chips, and mounting the wafer on a carrier board that has an insulating layer, a plurality of conductive circuits and a bottom board; forming a plurality of first grooves between solder pads of adjacent chips to expose the conductive circuits, then filling the first grooves with an insulating adhesive layer, and forming second grooves in the insulating adhesive layer, wherein the second grooves have a depth sufficient to at least reach locations of the conductive circuits of the carrier board such that a metal layer can be formed in the second grooves for electrically connecting the solder pads of adjacent chips and the conductive circuits; cutting between the chips to separate the chips on the carrier board from one another, and adhering a first tape on the chips; removing the bottom board of the carrier board to expose the conductive circuits and the insulating layer; adhering a second tape on the conductive circuits and the insulating layer; removing the first tape so as pick up the chips from the second tape, thereby forming a plurality of semiconductor devices. In the subsequent fabrication process, the conductive circuits of a semiconductor device can be thermally compressed and electrically connected to a substrate or the metal layer of another semiconductor device, thereby forming a 3-D multi-chip stack structure. Thus, more chips can be efficiently integrated in a package to improve electrical performance without increasing die attachment area. In addition, the present invention avoids poor electrical performance caused by using the wire bonding technique, and also avoids complicated fabrication process and high fabrication cost caused by using the TSV technique.

### Second Embodiment

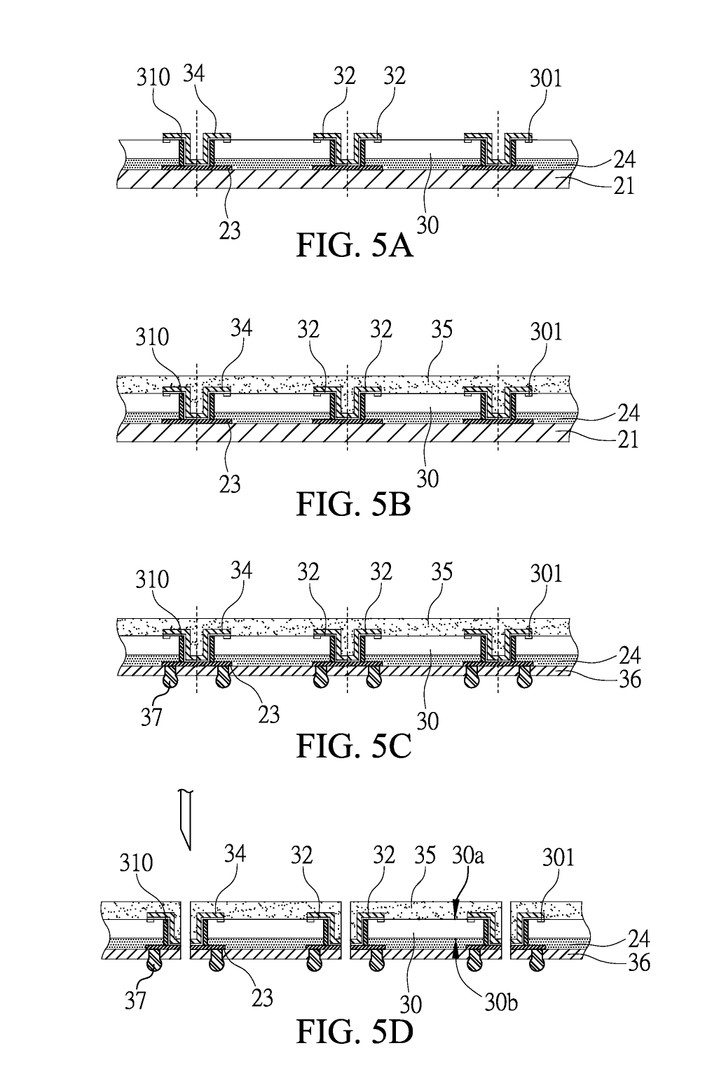

Please further refer to FIGS. 5A through 5D, which are diagrams of a semiconductor device and a fabrication method thereof according to the second embodiment of the present invention. For simplification, elements of the present embodiment that are same as or similar to those of the first embodiment are denoted with the same reference numerals.

As shown in FIGS. 5A and 5B, the semiconductor device and its fabrication method of the present embodiment are mostly similar to the first embodiment, the main difference therebetween is that after the metal layer 34 made of, for example copper/solder (Cu/Solder) or nickel/solder (Ni/Solder) is formed, a dielectric layer 35 is further formed on the active surfaces of the chips and the metal layer. The dielectric layer 35 is made of polyamide or an epoxy resin, for example.

As shown in FIG. 5C, the bottom board 21 is removed by means of etching, and a solder mask layer 36 such as green paint is formed on the insulating layer 24, and a plurality of apertures are formed in the solder mask layer 36 to expose the conductive circuits such that conductive elements 37 such as solder balls can be mounted thereon.

As shown in FIG. 5D, the whole structure is cut between the chips 30, thus to form a plurality of wafer-level chip scale semiconductor devices.

Hence, according to the embodiment of the present invention, the semiconductor device includes an insulating layer 24 having a top surface and an opposite bottom surface; conductive circuits 23 disposed on periphery of the bottom surface of the insulating layer 24; a solder mask layer 36 formed on the bottom surface of the insulating layer 24, the solder mask layer 36 having apertures to expose the conductive circuits 23; a chip 30 having an active surface 30a and an opposite non-active surface 30b, wherein the chip 30 is mounted on the top surface of the insulating layer 24 through its non-active surface 30b, and there are a plurality of solder pads 301 formed on the active surface 30a of the chip 30; an insulating adhesive layer 310 formed on sides of the chip 30 and the insulating layer 24; a metal layer 34 formed on edges of the active surfaces 30a of the chip 30 and sides of the insulating adhesive layer 310 for electrically connecting the solder pads 301 of the chip 30 and the conductive circuits 23 on the bottom surface of the insulating layer 24; and a dielectric layer 35 formed on the active surface 30a of the chip 30 and the metal layer 34. In addition, conductive elements 37 are mounted in the apertures of the solder mask layer 36, and a conductive layer 32 is formed between the metal layer 34 and the chip 30. The conductive layer 32 is an UBM layer.

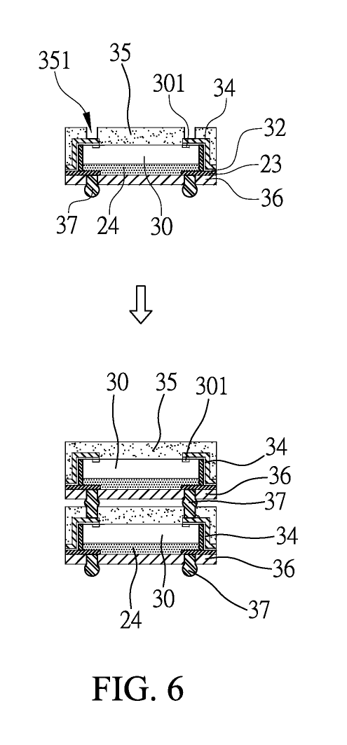

Referring to FIG. 6, in the subsequent fabrication process, apertures 351 are formed in the dielectric layer 35 to expose the metal layer 34, and the conductive elements 37 of the semiconductor device are thermally compressed and electrically connected to the metal layer 34 of another semiconductor device, thus forming a stack structure of semiconductor devices.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A fabrication method of a semiconductor device, comprising the steps of:
providing a carrier board and a wafer having a plurality of chips, wherein each of the wafer and the chips has an active surface and an opposite non-active surface, a plurality of solder pads are formed on the active surfaces of the chips, and the carrier board comprises a bottom board and a plurality of conductive circuits disposed on the bottom board, and the non-active surface of the wafer is attached to the bottom board of the carrier board and the conductive circuits through an insulating layer;
forming a plurality of first grooves between solder pads of adjacent chips;
filling the first grooves with an insulating adhesive layer, and forming second grooves in the insulating adhesive layer, wherein the second grooves have a depth sufficient to at least reach locations of the conductive circuits of the carrier board;
forming a metal layer in the second grooves for electrically connecting the solder pads of adjacent chips and the conductive circuits of the carrier board;
cutting among the chips to separate the chips on the carrier board from one another, and adhering a first tape on the chips;
removing the bottom board of the carrier board for exposing the conductive circuits and the insulating layer, and adhering a second tape on the conductive circuits and the insulating layer; and
removing the first tape so as to pick up the chips from the second tape, thereby forming a plurality of semiconductor devices.

2. The fabrication method of a semiconductor device of claim 1, wherein the carrier board is formed by the steps of:
providing the bottom board made of a metal material;
forming a first resist layer on the bottom board, and forming a plurality of apertures in the first resist layer for exposing the bottom board;
forming the conductive circuits in the apertures by electroplating; and
removing the first resist layer.

3. The fabrication method of a semiconductor device of claim 1, wherein the wafer is thinned before being mounted to the carrier board.

4. The fabrication method of a semiconductor device of claim 1, wherein a width of the second groove is smaller than that of the first groove such that part of the insulating adhesive layer is remained to cover sides of the chips, the cutting is performed in position to locations of the second grooves, a cutting width is smaller than the width of the second groove so as to remain part of the metal layer on edges of the active surfaces of the chips and the insulating adhesive layer beside the chips, thereby electrically connecting the solder pads of the chips and the conductive circuits through the metal layer, and a cutting depth is deeper than a depth of the second groove such that the adjacent chips are electrically separated from each other.

5. The fabrication method of a semiconductor device of claim 1, wherein the metal layer in the second grooves is formed by the steps of:
forming a conductive layer on the active surface of the wafer and inner surfaces of the second grooves;
forming a second resist layer on the conductive layer, and forming apertures in the second resist layer corresponding in position to the second grooves;
forming a metal layer in the apertures of the second resist layer for electrically connecting the solder pads of adjacent chips and the conductive circuits on the carrier board; and
removing the second resist layer and the conductive layer covered by the second resist layer.

6. The fabrication method of a semiconductor device of claim 5, wherein the conductive layer is an under bump metallurgy (UBM) layer formed by means of sputtering or vaporizing, and the conductive layer is made of one selected from the group consisting of titanium/copper/nickel (Ti/Cu/Ni), titanium wolfram/gold (TiW/Au), aluminum/nickel vanadium/copper (Al/NiV/Cu), titanium/nickel vanadium/copper (Ti/NiV/Cu), titanium wolfram/nickel (TiW/Ni), titanium/copper/copper (Ti/Cu/Cu), and titanium/copper/copper/nickel (Ti/Cu/Cu/Ni).

7. The fabrication method of a semiconductor device of claim 1, wherein the first tape and the second tape are one of an ultraviolet tape and a blue tape, the insulating adhesive layer is made of polyimide, the metal layer is made of one of copper/solder (Cu/Solder) and nickel/solder (Ni/Solder), and the insulating layer is made of one of B-stage epoxy resin and polyimide.

8. The fabrication method of a semiconductor device of claim 1, wherein the insulating layer is pre-disposed on the bottom board and the conductive circuits so as to become a part of the carrier board before the wafer is mounted thereto.

9. The fabrication method of a semiconductor device of claim 1, wherein the insulating layer is pre-disposed on the non-active surface of the wafer before the wafer is mounted to the conductive circuits and the bottom board of the carrier board.

10. A semiconductor device, comprising:
an insulating layer having a top surface and an opposite bottom surface;
conductive circuits disposed on periphery of the bottom surface of the insulating layer;
a chip having an active surface and an opposite non-active surface, wherein the non-active surface of the chip is mounted on the top surface of the insulating layer, and a plurality of solder pads are formed on the active surface of the chip;
an insulating adhesive layer formed on sides of the chip and the insulating layer; and
a metal layer formed on edges of the active surface of the chip and sides of the insulating adhesive layer for electrically connecting the solder pads of the chip and the conductive circuits on the bottom surface of the insulating layer.

11. The semiconductor device of claim 10, wherein the insulating layer is made of one of epoxy of a B-stage epoxy resin and polyimide, the metal layer is made of one of copper/solder and nickel/solder, and the insulating adhesive layer is made of polyimide.

12. The semiconductor device of claim 10, wherein the wafer is thinned.

13. The semiconductor device of claim 10, wherein a conductive layer is disposed between the metal layer and the insulating adhesive layer as well as the chip.

14. The semiconductor device of claim 13, wherein the conductive layer is an under bump metallurgy (UBM) layer, which is made of one selected from the group consisting of titanium/copper/nickel (Ti/Cu/Ni), titanium wolfram/gold (TiW/Au), aluminum/nickel vanadium/copper (Al/NiV/Cu), titanium/nickel vanadium/copper (Ti/NiV/Cu), titanium wolfram/nickel (TiW/Ni), titanium/copper/copper (Ti/Cu/Cu), and titanium/copper/copper/nickel (Ti/Cu/Cu/Ni).

15. A fabrication method of a semiconductor device, comprising the steps of:
providing a carrier board and a wafer having a plurality of chips, wherein each of the wafer and the chips has an active surface and an opposite non-active surface, a plurality of solder pads are formed on the active surface of the chips, and the carrier board comprises a bottom board, a plurality of conductive circuits disposed on the bottom board, the non-active surface of the wafer is attached to the bottom board and the conductive circuits of the carrier board through an insulating layer;
forming a plurality of first grooves between solder pads of adjacent chips;
filling the first grooves with an insulating adhesive layer, and forming second grooves in the insulating adhesive layer, wherein the second grooves have a depth sufficient to at least reach locations of the conductive circuits of the carrier board;
forming a metal layer in the second grooves for electrically connecting the solder pads of adjacent chips and the conductive circuits of the carrier board;
forming a dielectric layer on the active surfaces of the chips and the metal layer, and removing the bottom board of the carrier board to form a solder mask layer on the insulating layer, and forming apertures in the solder mask layer to expose the conductive circuits for conductive elements to be mounted thereon; and
cutting among the chips so as to form a plurality of semiconductor devices.

16. The fabrication method of a semiconductor device of claim 15, wherein the carrier board is formed by the steps of:
providing a bottom board made of a metal material;
forming a first resist layer on the bottom board, and forming a plurality of apertures in the first resist layer for exposing the bottom board;
forming the conductive circuits in the apertures by electroplating; and
removing the first resist layer.

17. The fabrication method of a semiconductor device of claim 15, wherein the wafer is thinned before being mounted to the carrier board.

18. The fabrication method of a semiconductor device of claim 15, wherein the insulating layer is made of one of B-stage epoxy resin and polyimide, the insulating adhesive layer is made of polyimide, the metal layer is made of one of copper/solder and nickel/solder, and the dielectric layer is made of one of polyimide and an epoxy resin.

19. The fabrication method of a semiconductor device of claim 15, wherein the metal layer in the second grooves is formed by the steps of:
forming a conductive layer on the active surface of the wafer and inner surfaces of the second grooves;
forming a second resist layer on the conductive layer, and forming a plurality of apertures in the second resist layer corresponding in position to the second grooves;
forming a metal layer in the apertures of the second resist layer for electrically connecting the solder pads of adjacent chips and the conductive circuits on the carrier board; and
removing the second resist layer and the conductive layer covered by the second resist layer.

20. The fabrication method of a semiconductor device of claim 19, wherein the conductive layer is an under bump metallurgy (UBM) layer formed by means of sputtering or vaporizing, and made of one selected the group of consisting of titanium/copper/nickel (Ti/Cu/Ni), titanium wolfram/gold (TiW/Au), aluminum/nickel vanadium/copper (Al/NiV/Cu), titanium/nickel vanadium/copper (Ti/NiV/Cu), titanium wolfram/nickel (TiW/Ni), titanium/copper/copper (Ti/Cu/Cu), and titanium/copper/copper/nickel (Ti/Cu/Cu/Ni).

21. The fabrication method of a semiconductor device of claim 15, wherein a width of the second groove is smaller than that of the first groove such that part of the insulating adhesive layer is remained to cover sides of the chips, the cutting is performed in position to locations of the second grooves, a cutting width is smaller than the width of the second groove so as to remain part of the metal layer on edges of the active surfaces of the chips and the insulating adhesive layer beside the chips, thereby electrically connecting the solder pads of the chips and the conductive circuits through the metal layer, and a cutting depth is deeper than a depth of the second groove such that the adjacent chips are electrically separated from each other.

22. The fabrication method of a semiconductor device of claim 15, wherein the insulating layer is pre-disposed on the bottom board and the conductive circuits so as to become a part of the carrier board before the wafer is mounted thereto.

23. The fabrication method of a semiconductor device of claim 15, wherein the insulating layer is pre-disposed on the non-active surface of the wafer before the wafer is mounted to the conductive circuits and the bottom board of the carrier board.

24. A semiconductor device, comprising:
an insulating layer having a top surface and an opposite bottom surface;
conductive circuits disposed on periphery of the bottom surface of the insulating layer;
a solder mask layer formed on the bottom surface of the insulating layer, wherein apertures are formed in the solder mask layer to expose the conductive circuits for conductive elements to be mounted thereon;
a chip having an active surface and an opposite non-active surface, wherein the non-active surface of the chip is mounted to the top surface of the insulating layer, and solder pads are formed on the active surface of the chip;
an insulating adhesive layer formed on sides of the chip and the insulating layer;
a metal layer formed on edges of the active surface of the chip and sides of the insulating adhesive layer for electrically connecting the solder pads of the chip and the conductive circuits on the bottom surface of the insulating layer; and
a dielectric layer covering the active surface of the chip and the metal layer.

25. The semiconductor device of claim 24, wherein the insulating layer is made of one of a B-stage epoxy resin and polyimide, the insulating adhesive layer is made of polyimide, the metal layer is made of one of copper/solder and nickel/solder, and the dielectric layer is made of one of polyimide and an epoxy resin.

26. The semiconductor device of claim 24, wherein the wafer is thinned.

27. The semiconductor device of claim 24, wherein a conductive layer is disposed between the metal layer and the insulating adhesive layer.

28. The semiconductor device of claim 27, wherein the conductive layer is an under bump metallurgy (UBM) layer, and made of one selected from the group consisting of titanium/copper/nickel (Ti/Cu/Ni), titanium wolfram/gold (TiW/Au), aluminum/nickel vanadium/copper (Al/NiV/Cu), titanium/nickel vanadium/copper (Ti/NiV/Cu), titanium wolfram/nickel (TiW/Ni), titanium/copper/copper (Ti/Cu/Cu), and titanium/copper/copper/nickel (Ti/Cu/Cu/Ni).
